(19) United States
(12) Patent Application Publication
(10) Pub. No.: US 2026/0362820 A1
(43) Pub. Date: Nov. 12, 2026

(54) POLYOLEFIN BASED BACKSHEET FOR PHOTOVOLTAIC PANELS

(71) Applicant: RKW SE, Mannheim (DE)

(72) Inventors: Adrien DEMBOWSKI, Mannheim (DE); Christoph SCHWEITZER, Mannheim (DE)

(73) Assignee: RKW SE, Mannheim (DE)

(21) Appl. No.: 19/111,887

(22) PCT Filed: Sep. 4, 2023
(86) PCT No.: PCT/EP2023/074119

§ 371 Date: Mar. 14, 2025

(30) Foreign Application Priority Data
Sep. 16, 2022 (DE) 102022123726.5

(51) Int. Cl. H10F 19/85

(52) U.S. Cl. CPC H10F 19/85

(57) ABSTRACT

A photovoltaic module with a translucent cover layer, an underlying layer containing at least one photovoltaically active cell which is embedded in an embedding material, and a backsheet (1) arranged underneath. The backsheet (1) is designed as a polyolefinic film with at least two layers (2, 3, 4). At least one layer (2) contains a black pigment. The backsheet (1) has a reflection of electromagnetic radiation in the range 800 to 1700 nm of more than 30 %, preferably more than 40 %, in particular more than 50 %.

### CROSS REFERENCE TO RELATED APPLICATIONS

This application is a 371 National Phase of PCT/EP2023/074119, filed Sep. 4, 2023, which claims priority from German Patent Application No 10 2022 123 726.5, filed Sep. 16, 2022, both of which are incorporated herein by reference as if fully set forth.

### TECHNICAL FIELD

The invention relates to a photovoltaic module with a translucent cover layer, an underlying layer containing at least one photovoltaically active cell which is embedded in an embedding material, and a backsheet arranged underneath, wherein the backsheet is designed as a polyolefinic film with at least two layers and wherein at least one layer contains a black pigment.

### BACKGROUND

Photovoltaic modules or solar modules are widely known and are increasingly being used for sustainable electricity generation. The photovoltaic cells convert the sunlight hitting the cells directly into electricity, which is dissipated via suitable electrical conductors and fed into a grid.

The cover layer can be made of glass with a thickness of 4-5 mm or a polymer front sheet, for example. The embedding material is usually based on ethylene vinyl acetate, which is applied as a film or strip to and around the electrically active cells and cross-linked by means of temperature.

The backsheet of these modules forms a back cover for the layer containing the photovoltaically active cells. It is known to form this backsheet from a fluoropolymer-based plastic film, as fluoropolymers are very temperature-resistant. The backsheet is formed as a laminate consisting of several layers, whereby the individual layers are bonded together using suitable laminating adhesives.

However, backsheets designed as multi-layer laminates have the disadvantage that the areas where the individual layers join represent weak points, as the layers can become detached from each other during prolonged use.

DE 10 2012 022 450 A1 discloses a photovoltaic module with a plastic-based backsheet that is free of laminating adhesive. The photovoltaic module has a frameless design and the backsheet has an adhesive-bonding finish at least on its upper and lower sides. At least one fastening element for fastening the photovoltaic module to a substructure is bonded to the underside of the backsheet.

The backsheet typically provides electrical insulation for the solar module and protects the photovoltaic module from environmental influences, mainly moisture. Backsheets typically contain several layers of different materials, with each material and each layer serving a different purpose. Most commonly, at least one of the materials contains a fluoropolymer. In addition to fluoropolymers, commonly used materials include polyethylene terephthalate (PET) polymers or polyethylene naphthalate (PEN) polymers.

This structure represents an economic and ecological disadvantage due to the ingredients, as these materials are comparatively expensive and environmentally incompatible. In many cases, bonding layers or other additional components must be provided in order to achieve sufficient cohesion of the individual layers to bond with each other and with the encapsulation layers of the solar module

Other backsheets comprise layers of polyester and/or polyamides. A disadvantage of many prior art materials is that the individual layers cannot be combined in a single process step to form a multi-layer backsheet, but must then be bonded together separately. Particularly with regard to the long-term stability of the comparatively unstable interlayer bond, this can lead to damage to the entire photovoltaic module.

EP 2 390 093 B1 describes a multilayer backsheet for solar modules, comprising an optional top layer, an insulating layer and a back layer, wherein the top layer, the insulating layer and the back layer contain a polyolefin as a main component, wherein the polyolefin is selected from polyethene homopolymers and copolymers, wherein the polyethene copolymers contain more than 50 mole percent ethene-derived units and contain alpha-olefin comonomers, and wherein the layers are coextruded and wherein the backsheet contains no layers between the layers. Polyolefin-based films can be recycled and from this point of view are more ecological than the known backsheets.

Many European countries have signed the European Plastics Pact. According to this pact, all packaging and plastic constructions must be designed in such a way that they are reusable or recyclable by 2025. The focus will therefore also be put on more sustainable product design, such as the construction of more mono-materials, better separation at source and further technical developments relating to automatic sorting and decoloring.

According to the state of the art, the backsheets used today for photovoltaic modules are black. To produce black backsheets, carbon black is usually added to the masterbatch before extrusion. However, carbon black has the disadvantage that the infrared radiation used to separate or sort the plastic streams in recycling is not reflected and therefore the plastic material cannot be fed to the appropriate grade. This means that a polyolefin backsheet cannot be separated by type and therefore cannot be recycled.

### SUMMARY

The object of the present invention is to provide a photovoltaic module with a backsheet that meets the requirements of the Plastics Pact 2025 and is fully recyclable. The backsheet should be able to be detected and separated in the known sorting systems. In addition, the backsheet should support the performance of the photovoltaic module in the best possible way. The backsheet should protect the photovoltaic module from environmental influences and ensure its use for as long as possible. The backsheet should also be harmless to health and ecologically sustainable.

According to the invention, this object is ensured by a photovoltaic module having one or more of the features disclosed herein as well as a method and a use having one or more of the features disclosed herein. Preferred variants can be found in the claims, the description, the embodiment example and the drawing.

According to the invention, the backsheet has a reflection of the electromagnetic radiation in the range 800 to 1700 nm of more than 30%, preferably more than 40%, in particular more than 50%.

Reflection refers to the reflection of waves at a boundary surface where the characteristic impedance or refractive index of the propagation medium changes. The angle of reflection corresponds exactly to the angle of incidence and both angles lie in the same plane with the perpendicular.

Near infrared or near-infrared (NIR) is the name given to the area of the electromagnetic spectrum that adjoins visible light in the direction of longer wavelengths. This range of infrared light extends from 780 to 3000 nm and thus comprises the IR-A and IR-B spectral ranges. The range of the infrared spectrum used for the detection of polymer material in recycling sorting plants is in the range from 800 to 1700 nm.

Ideally, at least one layer of the backsheet comprises a black pigment and is free of the soot that is normally used. Nevertheless, this layer has a high degree of blackness and can reflect infrared light. This increases the efficiency of the photovoltaic module and enables the polyolefin backsheet to be sorted in modern recycling plants.

In the case of a multi-layer backsheet, two or three or more layers may also contain a black pigment.

In a particularly favorable variant of the invention, the black pigment can be designed as an organic pigment.

Advantageously, the organic pigment can be a pigment or a pigment mixture from the perylene group. Perylene is a chemical compound from the substance class of polycyclic aromatic hydrocarbons. It is a solid that forms shiny yellow platelets. Substituted perylenes are strong in color and resistant to heat and usually to chemicals, which makes them particularly suitable for use in weathered photovoltaic modules.

Ideally, the black pigment, preferably the black organic pigment, can be present in the form of a masterbatch and mixed together with the polyolefinic starting material, in particular the polypropylene, melted and extruded to form a film.

In a favorable variant of the invention, the black layer has a proportion of a masterbatch with black pigment of more than 2% by weight, preferably of more than 4% by weight, in particular of more than 5% by weight and/or of less than 16% by weight, preferably of less than 12% by weight, in particular of less than 8% by weight. Even a small proportion of the masterbatch is sufficient for one layer to achieve the deep black formation of the layer and enable reflection of the infrared light.

In one variant of the invention, the black layer of the backsheet is non-reflective, but allows the electromagnetic radiation in the range from 800 to 1700 nm to be transmitted completely through the black layer.

In a particularly favorable variant of the invention, at least one layer of the backsheet is white, for example due to a proportion of titanium dioxide. Ideally, the white layer almost completely reflects the electromagnetic radiation in the range from 800 to 1700 nm.

In a particularly advantageous variant of the invention, the black transmitting layer and the white reflecting layer are arranged one above the other, with the black layer facing the photovoltaically active cells. Incident electromagnetic radiation is transmitted through the black layer and reflected by the white layer. The reflected electromagnetic radiation transmits through the black layer of the backsheet and enters the photovoltaically active cells, whereby the output of the photovoltaic module can be favorably increased.

In addition, a backsheet with a combination of a white and a black layer that reflects electromagnetic radiation in the range of 800 to 1700 nm can be detected by the sorting systems in recycling and is therefore also recyclable.

The special properties of the backsheet are achieved through the use and selection of special polymers.

Ideally, the backsheet is formed from a single-grade polypropylene whose density is more than 0.88 g/cm³, preferably more than 0.89 g/cm³ and/or less than 0.93 g/cm³, preferably less than 0.92 g/cm³ and/or whose melt flow rate according to ASTM 1238 (at 230 °C and 2.16 kg) is more than 0.6 g/10 min, preferably more than 0.7 g/10 min and/or less than 1.0 g/10 min, preferably less than 0.9 g/10 min.

It is particularly advantageous that the backsheet is not designed as a laminate and therefore no delamination processes can be initiated and/or favored by weather influences. The coextruded design significantly reduces the likelihood of a damaged backsheet and thus, in the medium term, a damaged or functionally impaired photovoltaic module.

Under these circumstances, it seems particularly advantageous that the backsheet is free of laminating adhesives. These can promote delamination of a laminated backsheet and thus lead to a defective photovoltaic module.

In terms of ecological design, the backsheet is free of fluoropolymers and/or comparable elements, which ensures that the backsheet can be recycled at the end of the photovoltaic module's useful life.

The filler content can be determined using known measurement methods such as ashing. A specimen with a known weight is heated to a temperature at which the polymer thermally decomposes but the filler does not. For example, 560 °C has proven to be a good temperature for this. The specimen weight is then measured again. The polymer content per square meter can be calculated using the difference between the weighed out and weighed in weight.

As an alternative to ashing, a TGA measurement is possible in which the weight of a specimen is measured continuously during heating. This test method can also clearly differentiate between polymer and filler and allows the polymer content of the film to be determined.

In a favorable variant of the invention, at least one further layer has an inorganic filler, the proportion of filler being more than 5% by weight, preferably more than 7.5% by weight, in particular more than 10% by weight.

Ideally, the filler is in the form of titanium dioxide, which makes it possible to achieve a white layer with an advantageous opacity.

Opacity is the opposite of transparency. It is a measure of opacity or opacity in percent. In particular, the opacity of a completely opaque film is 100% and a completely or fully transparent film has an opacity of 0%.

In a particularly favorable variant, the further layer of the backsheet has an opacity according to DIN 53416 of more than 55%, preferably more than 70%, in particular more than 80%. This means that the additional layer reflects infrared light almost completely.

In a particularly favorable variant, two or more layers of the backsheet have an inorganic filler in the form of titanium dioxide and reflect infrared light much more intensively.

In the variant of a three-layer backsheet, the middle layer is thicker by a factor than the two surrounding layers, whereby the factor is more than 1.25, preferably more than 1.5, in particular more than 1.75. Ideally, the middle layer has a proportion of titanium dioxide, as a result of which the infrared light can be reflected particularly well.

The thickness of the film was measured in accordance with DIN 53370 and specified as an average value. The backsheet has a thickness of less than 250 μm, preferably less than 210 μm, in particular less than 180 μm and/or more than 100 μm, preferably more than 130 μm, in particular more than 160 μm.

Ideally, the backsheet is particularly thin and saves material. Conventional and known backsheets are usually thicker in order to achieve the mechanical properties of the backsheet according to the invention. The design of the backsheet thus corresponds to the design specifications from the plastic package. Nevertheless, due to the special manufacturing process, the film has outstanding properties that result in an ideal backsheet, particularly for photovoltaic modules.

To realize the recyclability and thus also the sorting in modern waste separation plants, such as the float-sink process, the density of the backsheet is less than 1.00 g/cm³, preferably less than 0.99 g/cm³, in particular less than 0.98 g/cm³ and/or more than 0.70 g/cm³, preferably more than 0.80 g/cm³, in particular more than 0.90 g/cm³.

ISO 4892 specifies a procedure in which test specimens are exposed to xenon arc radiation and humidity in an apparatus to simulate the weathering effects that occur when materials are exposed to global radiation or global radiation behind window glass in real, end-use environments.

The test method described in ISO 4892-2 is also known as the xenon test, also known as the weather meter or light fastness test. The xenon test shows in a short time how well plastics are resistant to weather influences such as sunlight and rain. This is why this test method according to 4892-2 is also referred to as artificial rapid weathering.

In the xenon test according to ISO 4892-2, specimens are placed in a test chamber in which they are then exposed to a xenon arc lamp. This light is filtered so that exactly the same light is transmitted that the backsheet will be exposed to in practice. The most important filter types are the so-called daylight filters and window glass filters. Daylight filters illuminate the product with a spectrum that is very similar to the spectrum of sunlight. A window glass filter produces a light spectrum that corresponds to the sunlight falling through a standard window. This means that the specimens are protected from UV light, the cause of most damage to plastics.

Ideally, the backsheet has a UV resistance according to ISO 4892-2 of more than 15,000 h, preferably more than 17,500 h, in particular more than 20,000 h, and is therefore very resistant for use as a backsheet in a photovoltaic module that is installed outdoors and is subject to the effects of the weather.

Photovoltaic modules can become damaged if the rear wall in the form of the backsheet allows moisture to pass through. This can lead to delamination of the backsheet and/or a crack, but the front cover can also be damaged by moisture ingress, which leads to a significant reduction in the performance of the photovoltaic module.

The water vapor transmission is determined in accordance with DIN 53116 using a gravimetric measurement method. A test container filled with a desiccant is sealed with a specimen of backsheet film and exposed to a defined test climate. The amount of water permeating through the specimen is determined by weighing. A quantity of water in a range of 1-200 g/(m²·d) can be detected. The detection limit is also dependent on the composition and thickness of the specimen.

Ideally, the backsheet has a water vapor transmission rate of less than 20 g/(m²·d), preferably less than 2 g/(m²·d), in particular less than 1 g/(m²·d) according to DIN 53122-1 and is therefore ideally suited as a backsheet for photovoltaic modules.

Films and sheets with a thickness of up to 1 mm are tested using strip or shoulder specimen. According to ISO 527-3 and ASTM D 882, the usual specimen shape is the strip. This specimen shape can be produced easily using a cutting press or a film cutter. Shoulder specimen are often used in quality control. In this case, a direct measuring extensometer is required, with which the specimen elongations can be recorded directly on the specimen. Typical test results such as the yield stress, the elongation at yield, the maximum stress and the nominal elongation at break are recorded.

The tensile properties are determined in accordance with DIN EN ISO 527. In the tensile test, a test strip of backsheet film is stretched at a constant speed specified in the test standard and the force F is recorded with the change in length ΔL of the gauge length L₍₀₎.

Ideally, the backsheet has a tensile strength in the machine direction according to DIN EN ISO 527-3 of more than 500 MPa, preferably more than 650 MPa, in particular more than 750 MPa. This makes the backsheet film particularly stiff and tough, allowing the necessary tension to be realized as a backsheet film in a photovoltaic module.

Shrinkage or shrinkage of plastics refers to a change in the dimensional stability of test specimens at temperatures T>T_{G} (amorphous) or T>T_{S} (semi-crystalline), which is caused by the resetting of molecular orientations and the relaxation of residual stresses. The orientations arise as a result of the manufacturing process (extrusion, injection molding or deep drawing) and are therefore dependent on processing parameters. These parameters are the temperature of the tool and the melt, the injection and holding pressure, the flow path length and the cooling gradient of the backsheet film.

In a favourable variant of the invention, the backsheet has a shrinkage according to DIN 55543-4 of less than 10%, preferably less than 2%, in particular less than 1%. This makes the backsheet ideally suited to be resistant to the enormous temperature fluctuations between solar radiation in the middle of the day and cool night temperatures, without showing any expansion or shrinkage.

In an alternative variant of the invention, the backsheet can have an adhesive bonding layer. In this way, for example, a permanent bond with the embedding material can be achieved, which also lasts for years of outdoor use of a photovoltaic module.

The dielectric breakdown voltage is determined in accordance with ASTM D149. The tests are carried out at 60 Hz. There are three basic methods by which the dielectric strength of an insulator can be determined. These methods are the short-time method, the slow rise method and the step method. Each of these three methods has the same basic structure, which consists of placing the test specimen between two electrodes in air or oil.

For the most common test, the short-time method, a voltage is applied across the two electrodes and increased at a steady rate from zero to dielectric breakdown. Breakdown occurs when an electrical breakdown punctures the specimen or decomposition occurs in the specimen. The rate of voltage rise is determined by the time required for the specimen to reach dielectric breakdown.

The slow rise method starts at 50% of the breakdown voltage determined by the short-time method and is increased evenly.

The step-by-step procedure starts at 50% of the short-time test, then the voltage is increased in equal steps for a certain period of time until breakthrough. The test is sometimes performed in oil to prevent arcing from the electrode to the ground.

Advantageously, the backsheet has a dielectric breakdown voltage of at least 20 kV and can therefore form a safe backsheet for a photovoltaic module.

In an alternative variant of the invention, the backsheet can have a coating that provides additional protection against the penetration of moisture or other weather influences.

In a further variant of the invention, the photovoltaic module is designed without a frame. This can be realized particularly well by making the backsheet adhesive. As a result, the mass of the photovoltaic module can be significantly reduced and the photovoltaic module can also be flexibly attached to a wide variety of surfaces.

According to the invention, the process for producing a photovoltaic module comprises the following steps: The polypropylene is mixed with a masterbatch or with titanium dioxide and coextruded to form a backsheet having at least two layers. A proportion of a masterbatch with black pigment of more than 2% by weight, preferably more than 4% by weight, in particular more than 6% by weight and/or less than 16% by weight, preferably less than 12% by weight, in particular less than 8% by weight, is incorporated into at least one layer of the backsheet. With the aid of embedding material, for example ethylene vinyl acetate, the electrically active cell is bonded between a translucent layer and the backsheet to form a photovoltaic module.

According to the invention, a recyclable backsheet is used as a backsheet in a photovoltaic module.

### BRIEF DESCRIPTION OF THE DRAWINGS

Further advantages and features of the invention are apparent from the description of an embodiment example with reference to a drawing and from the drawing itself. This shows

FIG. 1 a schematic representation of the backsheet according to the invention.

### DETAILED DESCRIPTION

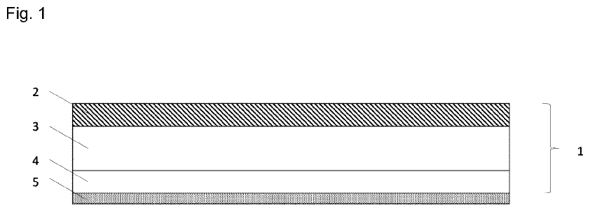

FIG. 1 shows a schematic representation of the backsheet 1 according to the invention. In this embodiment, the backsheet 1 has three layers 2, 3 and 4. Layers 2 and 4 are of approximately the same thickness, while layer 3 is twice as thick. Layers 3 and 4 are white and comprise a proportion of 10% by weight TiO₂. Layer 2 is black, faces the electrically active cell and contains 6% by weight of Avient masterbatch with the number PE 94000817. The backsheet 1 is made of a Repsol Inspire 137 polypropylene, is free of carbon black and reflects 60% of the electromagnetic radiation with a wavelength in the range from 800 to 1700 nm. In addition, the backsheet 1 has a coating 5 on the layer 4 facing the weathered environment, which protects the backsheet from the effects of the weather.

1. A photovoltaic module, comprising:
a. a translucent cover layer,
b. an underlying layer containing at least one photovoltaically active cell embedded in an embedding material,
c. a backsheet (1) arranged underneath,
i. the backsheet (1) being formed as a polyolefinic film having at least two layers,
ii. at least one of the layers (2) contains a black pigment, and
the backsheet (1) having a reflection of an electromagnetic radiation in a range 800 to 1700 nm of more than 30%.

2. The photovoltaic module according to claim 1, wherein the at least one of the layers has a proportion of a masterbatch with black pigment of more than 2% by weight and of less than 16% by weight.

3. The photovoltaic module according to claim 1, wherein the backsheet (1) is formed of a single-grade polypropylene having a density that is more than 0.88 g/cm³ and less than 0.93 g/cm³ and whose melt flow rate according to ASTM 1238 (at 230 °C and 2.16 kg) is more than 0.6 g/10 min and less than 1.0 g/10 min.

4. The photovoltaic module according to claim 1, wherein at least one further one of the layers (3, 4) has an inorganic filler, a proportion of the filler being more than 5% by weight.

5. The photovoltaic module according to claim 1, wherein the backsheet (1) has a thickness of less than 250 μm, and more than 100 μm.

6. The photovoltaic module according to claim 1, wherein the backsheet (1) has a UV resistance according to ISO 4892-2 of more than 15,000 h.

7. The photovoltaic module according to claim 1, wherein the backsheet (1) has a water vapour transmission rate of less than 20g/(m²·d) according to DIN 53122-1.

8. The photovoltaic module according to claim 1, wherein the backsheet (1) has a coating (5).

9. The photovoltaic module according to claim 1, wherein the backsheet (1) has a tensile strength in the machine direction according to DIN EN ISO 527-3 of more than 500 MPa.

10. The photovoltaic module according to claim 1, wherein the backsheet (1) has an adhesive bonding layer.

11. The photovoltaic module according to claim 1, wherein the backsheet (1) has a dielectric breakdown voltage of at least 20 kV.

12. The photovoltaic module according to claim 1, wherein the at least two layers comprise first, second, and third layers, the second layer (3) is thicker by a factor than the first and third layers (2, 4), the factor being more than 1.25.

13. A method of manufacturing a photovoltaic module comprising the following steps
coextruding backsheet (1),
connecting a translucent tray with an electrically active cell and the backsheet (1) with an embedding material to form the photovoltaic module,
wherein
that at least one layer (2) of the backsheet incorporates a proportion of a masterbatch with black pigment of more than 2% by weight and of less than 16% by weight.

14. The method of claim 13, wherein the backsheet (1) is a recyclable backsheet (1), and the method includes using the recyclable backsheet as the backsheet in the photovoltaic module.
